(19) United States
(12) Patent Application Publication
(10) Pub. No.: US 2015/0288318 A1
(43) Pub. Date: Oct. 8, 2015

(54) REFRACTORY PLASMONIC METAMATERIAL ABSORBER AND EMITTER FOR ENERGY HARVESTING

(71) Applicant: PRF, West Lafayette, IN (US)

(72) Inventors: Urcan Guler, Lafayette, IN (US); Alexander Kildishev, West Lafayette, IN (US); Vladimir M. Shalaev, West Lafayette, IN (US); Alexandra Boltasseva, West Lafayette, IN (US); Gururaj Naik, West Lafayette, IN (US)

(21) Appl. No.: 14/402,343

(22) PCT Filed: Jun. 6, 2014
(86) PCT No.: PCT/US2014/041238

§ 371 Date: Nov. 20, 2014

Related U.S. Application Data
(60) Provisional application No. 61/876,241, filed on Sep. 11, 2013.
(60) Provisional application No. 61/934,786, filed on Feb. 2, 2014.

(51) Int. Cl. H02S 10/30; H01L 31/055

(52) U.S. Cl. CPC H02S 10/30; H01L 31/055

(57) ABSTRACT

The present invention provides a new system and new devices comprising highly efficient metamaterial-based absorbers and emitters which may be employed in various energy harvesting applications Compelling conditions such as high temperatures. The employment of ceramic materials in such applications enables devices with longer lifetimes and improved performance. Specific geometric and structural designs, e.g., by arrangement of plasmonic and dielectric structures, of the metamaterials provide for efficient absorption of light within a broad spectral range and emission of that energy in a particular range via selective emitters which may, in turn, be coupled to other devices.

### REFERENCE TO RELATED APPLICATIONS

This patent application is a National stage application for PCT application PCT/US14/41238, which claims priority to, and incorporates fully by reference, U.S. Provisional Patent Application No. 61/876,241, filed Sep. 9, 2013, and U.S. Provisional Patent Application No. 61/934,786, filed Feb. 2, 2014.

### FIELD OF THE INVENTION

The present disclosure relates to plasmonics, and in particular, to the composition and arrangement of plasmonic nanostructures for light harvesting applications including but not limited to solar/thermo-photovoltaic, thermo-photovoltaic, and solar thermoelectric devices, based on the broadband absorption of light in the visible and near-infrared spectrums and selective emission with a spectrum matched to a photovoltaic cell.

### BACKGROUND OF THE INVENTION

Plasmonics applications rely on the coupling of electromagnetic waves to plasmon in metallic materials. Plasmon is the collective oscillation of electrons along the surface of a metal in response to an externally applied electromagnetic field. With high free electron densities, metals are known to exhibit strong plasmonic responses and have been very popular in the area of plasmonics. The optical properties of the metal employed in a plasmonic device strongly and directly affect that device's performance.

Metals such as gold and silver exhibit plasmonic resonances in the visible range with high efficiency. However, their softness, low melting points, and chemical activity limit the performance of devices comprised of metals such as gold and silver. Hard materials with good plasmonic properties and other superior properties, such as high melting point and chemical inertness, are required for applications under extreme conditions.

Noble metals, in particular gold and silver, have been the popular choice for plasmonic devices and research due to lower optical losses in the visible and near infrared region. However, both materials have applicability problems associated with metal properties. First, optical properties of metals cannot be tuned in order to fit into specific applications. Second, fabricating ultra-thin films of gold and silver is challenging and even nearly impossible for some cases. Third, nanostructured silver and gold are not mechanically stable at elevated temperatures. Relatively low melting points of these materials become a problem for high temperature applications, as the melting points for nanostructured metals are even lower. Fourth, silver is chemically instable and causes problems in many applications such as sensing. Fifth, neither metal is complementary metal oxide semiconductor- (CMOS-) compatible, hence posing challenges in the integration of plasmonic devices with widely used CMOS devices.

In addition to those references listed further herein, the following references are incorporated herein by reference in their entirety: Chen, W., et al., Ultra-thin ultra-smooth and low-loss silver films on a germanium wetting layer. Opt. Express, 2010. 18(5): p. 5124-5134; Guler, U. and R. Turan, Effect of particle properties and light polarization on the plasmonic resonances in metallic nanoparticles. Opt Express, 2010. 18(16): p. 17322-38; Naik, G. V., et al., Titanium nitride as a plasmonic material for visible and near-infrared wavelengths. Optical Materials Express, 2012. 2(4): p. 478-489; Guler, U., et al., Performance analysis of nitride alternative plasmonic materials for localized surface plasmon applications. Applied Physics B, 2012. 107(2): p. 285-291; and Guler, U., et al., Local Heating with Lithographically Fabricated Plasmonic Titanium Nitride Nanoparticles. Nano Letters, 2013. 13(12): p. 6078-6083.

### BRIEF DESCRIPTION OF FIGURES

FIG. 1(a) depicts a side view of an example metamaterial design that may be optimized as a broadband absorber or selective emitter, as disclosed herein.

FIG. 1(b) depicts a top view of part of the metamaterial arrangement example of FIG. 1(a).

FIG. 1(c) depicts examples of various geometries of plasmonic nanostructures for the metamaterials discussed herein.

FIG. 2 depicts a planar solar/thermophotovoltaic arrangement based on the metamaterial absorber and emitter design disclosed herein.

FIGS. 3(a) through 3(f) depict examples of schematics of top-down process steps for making the absorber and emitter metamaterial arrangements of the example in FIG. 1.

FIGS. 4(a) and 4(b) depict example schematics of process steps for making the absorber and emitter metamaterials disclosed herein via thin film deposition and colloidal samples.

FIG. 4(c) depicts a perspective view of a metamaterial absorber/emitter with a non-periodic arrangement of plasmonic nanostructures.

FIG. 4(d) depicts absorption/emission spectra for the metamaterial arrangement shown in FIG. 4(c), corresponding to varying thicknesses of the spacer layer, h₂.

FIG. 5 depicts an assembly example of a metamaterial broadband absorber and selective emitter with a shared plasmonic backplane enabling ultrathin spectral conversion (via ultrathin spectral converter).

FIG. 6 depicts a cross-sectional view of an example assembly of spectral converters arranged in a cuboid shape with one open face for efficient absorption of solar irradiation.

FIG. 7(a) depicts a top view of an example of an ultra-thin selective emitter metamaterial integrated into a non-planar surface.

FIG. 7(b) depicts a perspective view of an example cylindrical arrangement of a spectral converter as disclosed herein.

FIG. 8 depicts an example schematic of the integration of a broadband metamaterial abosorber, as disclosed herein, with a thermoelectric device.

FIG. 9 depicts a multilayer planar arrangement example for broadband absorber and selective emitter metamaterials, as disclosed herein, comprising high temperature plasmonic and dielectric materials.

FIG. 10 depicts a near field arrangement example for high efficiency energy transfer between a selective emitter metamaterial and a photovoltaic cell. A thin layer of thermal insulator and liquid/gas flow for semiconductor cooling is applied where both elements have to be transparent in the spectral region of radiation from the emitter.

FIGS. 11(a) and 11(b) depict the scanning electron microscope (SEM) images of rectangular rings made of gold (FIG. 11(a)) and titanium nitride (FIG. 11(b)) before being illuminated with laser pulses. FIGS. 11(c) and 11(d) show the same rectangular rings after being illuminated with laser pulses at 550 nm wavelength. FIG. 11(c) shows gold structures damaged while FIG. 11(d) shows titanium nitride structures substantially undamaged.

FIG. 12(a) depicts an SEM image of a TiN metamaterial absorber after annealing at 800° C. FIG. 12(b) depicts an SEM image of an Au metamaterial absorber after annealing at 800° C.

FIG. 12(c) depicts a graph of absorptivity versus wavelength (nm). The graph shows optical transmittance data for samples before and after annealing.

FIG. 13 depicts a graph of absorption and emission versus wavelength (nm) for solar irradiance (dotted line), the absorption spectrum of a TiN absorber according to the present invention (solid line), the narrowband emission peak from a TiN selective emitter metamaterial according to the present invention (dashed-dotted line), and the emission spectrum of a blackbody at 1500° C. (dashed line). Wavelengths corresponding to the bandgap energies of semiconductors are provided for reference as well (vertical dashed lines).

FIG. 14 depicts a schematic example of a metamaterial design according to the present invention with an additional protective layer against oxidation of refractory material.

FIG. 15 depicts an example of a perforated metallic film as described herein, which may comprise an emitter as described herein. FIG. 15(a) is a 2-dimensional view of the film, and FIG. 15(b) is a 3-dimensional view of the film.

### SUMMARY OF THE INVENTION

In one aspect, a solar thermophotovoltaic system according to the present invention comprises a selective refractory metamaterial ultimate absorber configured to absorb electromagnetic energy in the visible and near infrared spectral region, and heating to temperatures above 100 degrees Celsius where a blackbody emission in the near infrared spectral region is enabled, which is coupled to a selective refractory metamaterial emitter configured to radiate electromagnetic energy matching with a bandgap of a photovoltaic semiconductor in the near infrared spectral region (or alternatively, a thermoelectric device).

In some aspects, the absorber comprises a backplane thin film of a refractory plasmonic material, a spacer comprising a thin film of a refractory dielectric material, and a first arrangement of nanostructures (also comprising thin films) of a refractory plasmonic material.

In some aspects, the emitter comprises a backplane thin film of a refractory plasmonic material, a spacer comprising a thin film of a refractory dielectric material, and a second arrangement of nanostructures of a refractory plasmonic material.

In some aspects, the backplane thin film forms a bottom layer of the absorber, the first arrangement of nanostructures forms a top layer of the absorber, and the spacer is located between the bottom and top layers, together forming an arrangement to convert electromagnetic energy into heat energy.

In some aspects, the emitter releases spectrally selective radiation in a near infrared spectral region. In some aspects, the arrangements of nanostructures comprise a periodic arrangement of repeating individual nanostructure cells. In other aspects, the arrangements of nanostructures comprise a non-periodic arrangement of repeating individual nanostructure cells, wherein an individual nanostructure cell comprises a shape of sub-wavelength width, d, and a height between 5 nm and 500 nm, each cell being separated by a pitch distance, p, between 20 nm and 1,000 nm, defined by a relationship of 1 p/6<d<5 p/6.

In some aspects, the backplane thin film has a thickness of at least 100 nm. In some aspects, the spacer has a thickness between 1 nm and 1000 nm.

In some aspects, the nanostructures comprise metal-nitrides, borides, oxides, carbides, sulfides, or a combination thereof. In some aspects, the nanostructures comprise refractory metals with a dielectric permittivity exhibiting zero cross-over with a visible spectral region. In some aspects, the nanostructures comprise tantalum. The arrangements of nanostructures comprise shapes including but not limited to nanospheres, nanodisks, nanorods, nanocubes, nanotriangles, nanostars, or a combination thereof.

In some aspects, the emitter exhibits selective emission at a wavelength between 700 nm and 3,000 nm.

In another aspect, the emitter may comprise a perforated metallic film with a thickness greater than 50 nm and with perforations smaller than 3000 nm, in a periodic or a random arrangement.

In some aspects, the absorber and the emitter may further comprise a coating of an optically transparent film for oxidation resistance, the coating having a thickness between 5 nm and 3,000 nm.

Also disclosed is a thermophotovoltaic system comprising a selective emitter coupled to a heat source other than an absorber (e.g. a natural heat source, a specifically designed furnace burning fuel, a source of residual heat from another technological process or system). The emitter obtains heat via the other heat source (thus not requiring sunlight) and emits a selected wavelength radiation for specifically illuminating a photovoltaic cell, which in turn produces electric power.

In some aspects, the system is fabricated using a lithographic method. In other aspects, the system is fabricated using powder dispersion or powder metallurgy.

### DETAILED DESCRIPTION OF THE PREFERRED EMBODIMENT

### Definitions

“Ceramics.” In addition to TiN, the plasmonic materials discussed herein may comprise several other nonstoichiometric binary compounds including, but not limited to, ZrNx, HfNx, TaNx, VNx, TiSi2-x, or ternary compounds such as TiAlxNy and TiZrxNy. The non-stoichiometric compounds utilized as described by the present disclosure make up the class of ceramics, further defined as metal and intermetallic nitrides, oxides, carbides, borides including nitrides, oxides, carbides, borides with all combinations of metals (e.g. TiN, ZrN, TaN, TiZrN, AlN etc.). Any of the elements discussed herein (i.e. the thin films of varying functions) may comprise such materials (for example, the backplane thin film, the spacer, the nanostructures, and the protective coating layer). Thus, it should be noted that throughout the present disclosure, any of the compounds listed here, as well as other compounds within this class, can be substituted for other refractory plasmonic (meta)materials or refractory dielectric (meta)materials to perform in a similar manner

“Ultimate absorber.” As used herein, this term is defined as a near 100% absorber (i.e. near perfect), which is capable of absorbing nearly all (99.9%) of a particular electromagnetic radiation directed towards it. The terms “ultimate” and “near perfect,” as used herein, are interchangeable.

“Selective refractive metamaterial.” As used herein, this term refers to the composition of the ultimate absorber as well as the composition of the emitter (described further below) comprising the system of the present invention. The term also clarifies the fact that the absorber only absorbs chosen wavelengths, a feature which may be adjusted to fit specific wavelengths by, e.g., changing growth parameters. This adjustability is further described herein.

The present disclosure provides a new system and devices comprising metamaterial-based near perfect absorbers which may be employed in various applications compelling conditions such as high temperatures. The employment of ceramic materials in such applications enables devices with longer lifetimes and improved performance Impedance matching designs of metamaterials provides efficient absorption of light within a broad spectral range Impedance matching in such designs may occur, for example, by the arrangement of plasmonic structures with a dielectric spacer. Metal nitrides provide efficient plasmonic absorption and may be used as the plasmonic material in a metamaterial near perfect absorber. In addition to their high optical performance, metal nitrides are also mechanically, thermally, and chemically stable. Other nitride compounds, such as silicon nitride (generally referred to as ceramic material), may be used as the dielectric spacer material in the design of the metamaterial near perfect absorber. In addition to their dielectric properties, the relatively higher melting points of such ceramic materials increase the resistance of a device according to the present invention to high-temperature operating conditions. Dielectric refractory materials include but are not limited to oxides, nitrides, carbides, or a combination thereof. By using ceramic materials for all components of the design, a fabrication process compatible with silicon technology is achieved. Near perfect absorbers capable of high temperature operation are necessary elements of thermophotovoltaic devices. For this particular application, an emitter for a narrow spectral range (a selective emitter) may comprise plasmonic metal nitride structures, wherein the semiconductor material is made of any commonly used material(s) such as silicon, germanium, gallium antimonide, indium gallium arsenide, etc.

One example of a plasmonic metal nitride is titanium nitride (TiN). Titanium nitride is one of the hardest materials with a very high melting point (>2700° C.). TiN is CMOS-compatible, bio-compatible, and may be grown as high quality ultra-thin films or as nanostructured films (the designs disclosed herein may be fabricated using any known method in the art, including but not limited to lithography, thin film deposition, powder dispersion, and powder metallurgy). Lithography includes but is not limited to electron beam lithography, photolithography, laser interference lithography, block copolymer lithography, nanoimprint lithography, etc. Thin film deposition includes but is not limited to magnetron sputtering, atomic layer deposition, pulsed laser deposition, etc. The properties mentioned make TiN a better alternative plasmonic material. TiN has been demonstrated to support surface plasmon-polaritons (SPPs), and TiN nanostructures have been shown to exhibit localized surface plasmon resonance (LSPR) [5-7].

The strength of the LSPR in TiN nanoparticles is similar to that of gold nanoparticles, but it occurs in a broad wavelength range of about 850 nm [6]. LSPR greatly enhances the electromagnetic field around the nanoparticle, and it also causes the metal particle to absorb much more radiation than it would without LSPR. Such excessive absorption of optical radiation causes the nanoparticle to locally heat its surroundings. Local heating is useful in applications for efficient heating for energy harvesting including, but not limited to, solar steam generation, thermophotovoltaics, etc.

TiN and other ceramic material nanostructures are a better substitute to noble metal nanostructures given their biocompatibility, thermal stability, and comparably greater performance in the presence of heat. Based on their non-stoichiometric nature, plasmonic metal nitrides may be fabricated with varying optical response by changing growth parameters. Depending on the application, the dielectric permittivity of the material may be tuned for optimal performance For example, in the case requiring near perfect absorbers where reflection is to be avoided, plasmonic materials with relatively weaker metallic properties are desired. In such a case, TiN may be grown to have a dielectric permittivity closer to zero when compared to noble metals, and it would be less reflective.

The system of the present invention generally comprises a selective refractory metamaterial ultimate absorber configured to absorb electromagnetic energy in the visible and near infrared spectral region, which is capable of heating up to high temperatures (e.g., above 100 degrees Celsius) where a blackbody emission in the near infrared spectral region is enabled. The system further generally comprises a selective refractory metamaterial emitter configured to radiate the electromagnetic energy absorbed by the absorber and transferred to the emitter with its emission band matching with a band gap of a photovoltaic semiconductor in the near infrared spectral region. Thus, the system comprises an ultimate absorber, coupled to an emitter, coupled to a photovoltaic semiconductor.

The ultimate absorber and emitter designs described herein may further comprise a refractory plasmonic metal nitride nansotructure array (i.e. an arrangement of nanostructures of a refractory plasmonic material) forming a top layer, a plasmonic metal nitride backreflector (i.e. a backplane thin film of a refractory plasmonic material) forming a bottom layer, and a dielectric nitride compound forming a spacer (i.e. a spacer comprising a thin film of a refractory dielectric material) which is placed between the two layers. The plasmonic metal nitride nanostructures may comprise, for example, rectangular rings having sub-wavelength dimensions. The nanostructures are helpful in engineering the electric and magnetic response of the interface between the air and the substrate, as they provide impedance matching. Matched impedance reduces reflection dramatically and enhances the absorption of light by the system described herein. The nanostructures may have symmetric geometry to provide for polarization independent operation.

Alternatively, the emitter may comprise a perforated metallic film with a thickness greater than 50 nm, and with perforations (i.e. holes) smaller than 3000 nm (in diameter). These perforations may be arranged in either a periodic arrangement or a random (non-periodic) arrangement. FIG. 15 shows an example of a perforated metallic film according to the present invention, which sometimes comprises the emitter described herein. FIG. 15(a) is a 2-dimensional view of the film, and FIG. 15(b) is a 3-dimensional view of the film. Such perforated metallic film structures are used today in experimental research with other known refractory metals (e.g., tungsten, tantalum, etc.), and similar structures are incorporated into the present disclosure as potential substitutes for another embodiment of a selective emitter as described herein.

Refractory plasmonic materials meet certain criteria required for efficient performance of energy harvesting devices, and are particularly applicable to such devices operating at temperatures of above 100° C.

Plasmonic nanoparticles with sizes comparable to the wavelength of incident light exhibit localized surface plasmon resonances (LSPR). Dipolar resonances occur in particles that are smaller compared to the wavelength of light while higher order modes can be observed with increasing particle dimensions and engineered shapes (See US 2009/0326614 A1, to El-Sayed et al.). Plasmon oscillations at resonant wavelengths (also referred to herein as “resonance wavelengths”) provide large field enhancements and temperature increases in the vicinity of plasmonic particles.

Nanostructures comprising plasmonic materials may be used for matching of impedance between incident medium and the substrate. Matched impedance surfaces reduce the reflection of electromagnetic waves and enhance the absorption of light through the body of a device as disclosed herein.

Metamaterials with broad absorption peaks at particular regions of the electromagnetic spectrum may be engineered by impedance matching with sub-wavelength plasmonic structures. The nanostructures described herein include but are not limited to nanospheres, nanodisks, nanorods, nanocubes, nanotriangles, providing broadband absorption in the visible and near infrared regions. Substantially all of the electromagnetic energy incident on the surface at a particular spectral window is absorbed through the substrate, thus resulting in a near perfect absorber. The incident energy is absorbed with an efficiency of nearly 100 percent.

One method for energy harvesting from the Sun is the use of thermophotovoltaic devices with efficient absorbers to convert the Sun's emission in the visible region into heat energy and re-radiate that energy at wavelengths matching the bandgap of a semiconductor device for efficient photocurrent collection (See US 2012/0312360 A1, to Shvets et al.).

The amount of heat power delivered to the medium is directly proportional to the power of illuminating light and the rate of absorption. The engineered surfaces for near perfect absorption disclosed herein may be used for efficient conversion of electromagnetic energy to heat energy.

The design of the present invention provides the ability to operate at high temperatures due to the high melting points of the ceramic materials comprising the devices described herein. The accompanying figures, as discussed below, further illustrate the present invention.

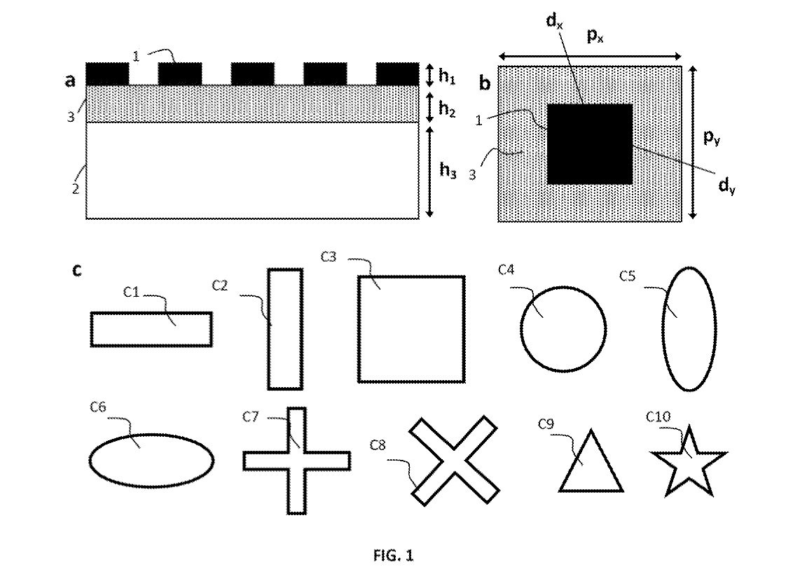

FIG. 1.a shows a side view of an exemplary metamaterial near perfect absorber or selective emitter design, according to the present disclosure. The metamaterial design of this example comprises refractory plasmonic nanostructures 1, a thin film backreflector (i.e., a backplane thin film) 2, and a refractory dielectric compound forming a spacer 3. FIG. 1.b shows the design of the portion of one nanostructure of FIG. 1.a from a top view perspective. FIG. 1.c shows examples of nanostructure geometries for the broadband absorber and/or selective emitter designs discussed herein (e.g., rectangular (C1, C2), square (C3), circular (C4), elliptical (C5, C6), cross-like (C8, C9), triangular (C9), or star-like (C10). Nanostructures of various shapes are employed in order to provide impedance matching and increase absorption of the device. The designs shown in the figure are only exemplary and may be further modified in order to achieve similar performance.

The backplane (e.g., in the exemplary design of FIG. 1) may comprise the same plasmonic material as the nanostructures, or it may comprise another plasmonic material, depending on particular application conditions and requirements. In the particular design of FIG. 1, both the nanostructures and the backplane comprise titanium nitride due to its good optical performance (e.g., stability at high temperature, etc.). The dielectric spacer layer, in the same example, is silicon nitride due to its high melting point, allowing operation at elevated temperatures, transparency in the electromagnetic region of interest, and compatibility with the particular plasmonic material. A variety of ceramic materials, both plasmonic and dielectric, may be used in similar designs with high temperature operation capabilities.

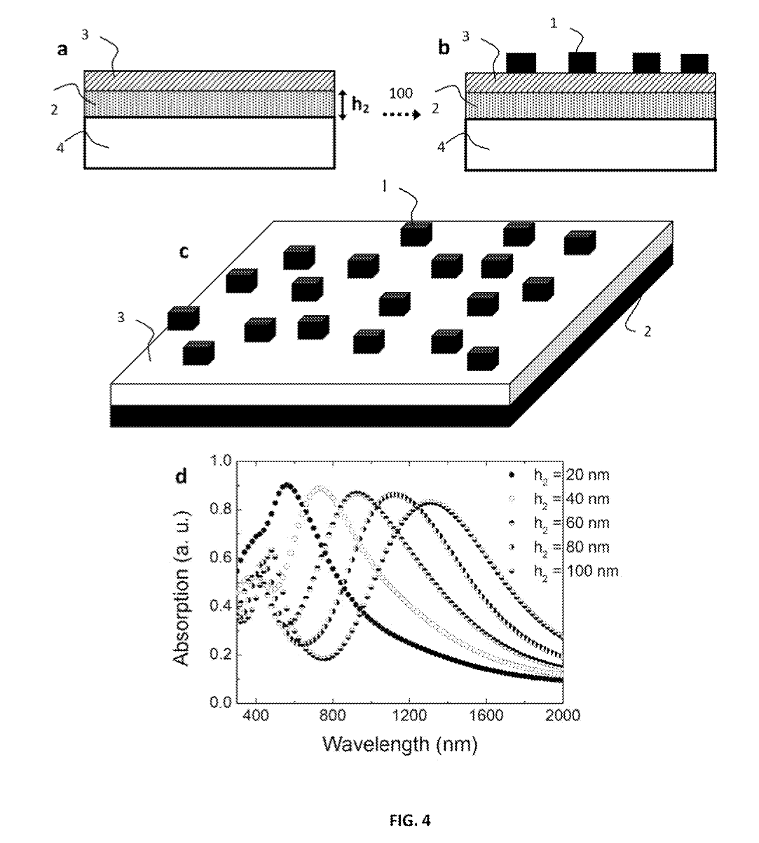

Referring specifically to FIGS. 1.a and 1.b, an exemplary refractory plasmonic nanostructure is depicted. The devices described herein may comprise one or more nanostructures in periodic repeating cells (e.g., FIG. 1.a) or non-periodic repeating cells (e.g., see FIG. 4.c). The dimensions of each cell are represented by the following variables: dₓ and d_{y} (representing the width of a rectangular nanoparticle cell in two directions), h₁ (representing the thickness of the nanoparticle cell), pₓ and p_{y} (representing the pitch of the cell), h₂ (representing the thickness of the refractory dielectric compound used as a spacer, which is between 1 nm and 1,000 nm), and h₃ (representing the thickness of the backplane thin film, which is at least 100 nm). The range of these variables may be, for example: 20 nm<pₓ<1000 nm, 20 nm<p_{y}<1000 nm, 5 pₓ/6<dₓ<3 pₓ/6, 5 p_{y}/6<d_{y}<3 p_{y}/6, 5 nm<h₁<500 nm, 1 nm<h₂<1000 nm, h₃>100 nm, and preferably >150 nm for particular light conditions and materials. As discussed herein, the design and dimensions of the cells play a role in the overall design of refractory plasmonic nanostructures and in configuring them to provide their selectivity and bandwidth, thereby defining their absorption or emission bands (depending on the desired application).

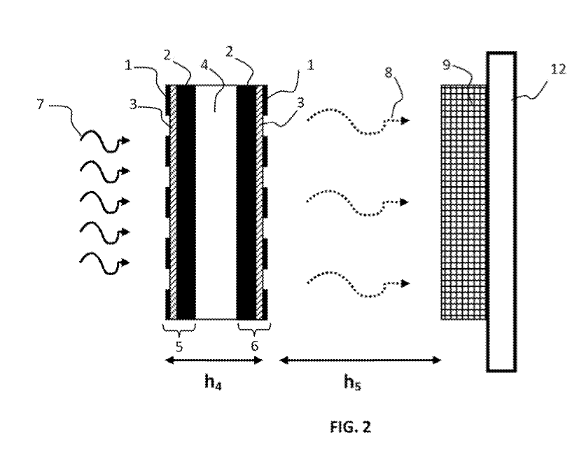

FIG. 2 illustrates an example design of a solar thermophotovoltaic system for natural application of the near perfect absorber and selective emitter metamaterials described herein. The system comprises a near perfect absorber 5 for absorbing electromagnetic energy in the visible spectral region from the Sun 7, a body acting as a blackbody at elevated temperatures 4, and a selective emitter metamaterial 6 engineered to emit light with longer wavelengths 8 for efficient absorption by a photovoltaic cell 9 (the emitter is configured such that its emitted wavelength matches with the band gap of the photovoltaic cell, in the near infrared spectral region). The emitter may be configured to emit radiation at wavelengths between 700 nm and 3,000 nm, for example. Components of any of these layers/elements may comprise oxides, carbides, nitrides, or a combination thereof or any other similar compounds which are capable of operation at high temperatures. The body acting as a blackbody 4 may be any material that is capable of operation at high temperatures, and preferably has high thermal conductivity and an expansion coefficient similar to the refractory plasmonic material used (examples are sapphire, silicon nitride, etc.).

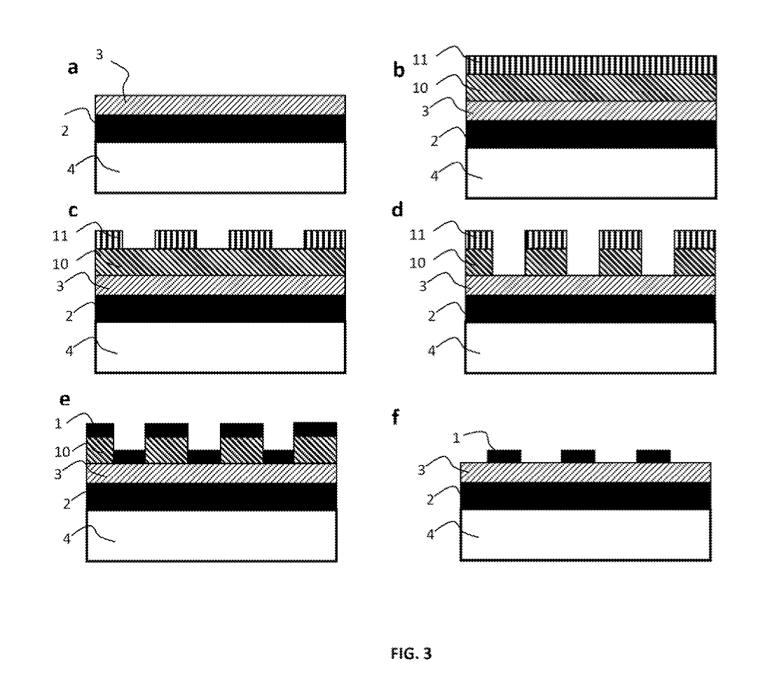

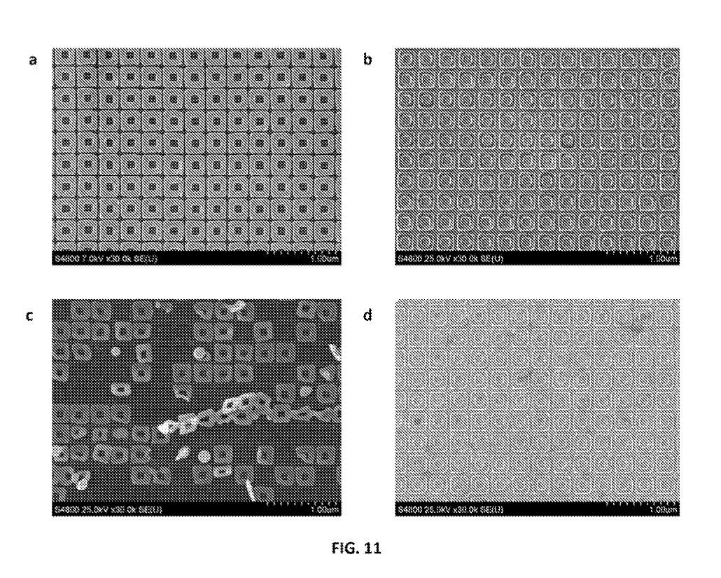

Referring to FIG. 3, a series of example top-down schematics (a (i.e. step 1) f (i.e. step 6)) are depicted to show an exemplary process for making the metamaterial arrangement according to the present invention. Nanostructures of plasmonic materials may be fabricated lithographically. The scanning electron microscope images of FIG. 11 (comparing gold to TiN) correspond to the structures illustrated in FIG. 3. Due to the high temperature deposition of titanium nitride thin film, a standard lithography process is modified so that the lithography pattern is transferred onto a lift-off material with high temperature stability 10. This layer is required for high temperature nitride deposition (or any other deposited material according to the present invention). FIG. 3 shows how reactive ion etching is used for the transfer, from an electron beam resist/photoresist layer 11, of a nanostructure pattern onto a chromium thin film (depicted by 10, although this may comprise a material other than chromium), which is removed with, e.g., chrome etchant after titanium nitride (depicted by 1, although this may comprise a material other than TiN) deposition. The process may be modified in various ways such as substitution of wet etching for reactive ion etching, chromium lift-off layer by another high temperature material with etch selectivity for plasmonic and dielectric materials used in the design, etc. Low temperature deposition techniques may be employed in order to completely cancel the pattern transfer process to the chromium layer.

FIGS. 4(a) and 4(b) illustrate the fabrication of a metamaterial absorber or emitter coupled to a substrate 4 by thin film deposition of a backplane 2 and spacer 3 (FIG. 4(a)), which is followed by colloidal dispersion 100 of refractory plasmonic nanoparticles 1 (FIG. 4(b)). FIG. 4(c) shows a perspective view of an example of a sample fabricated by a colloidal dispersion method to achieve a non-periodic nanostructure arrangement. FIG. 4(d) shows the calculated absorption and emission peaks of this particular arrangement with varying spacer layer thicknesses. As the figure shows, by adjusting the parameter, h₂, the resonance peak may be shifted to match the visible and near infrared region where a particular absorber and emitter according to the present invention operates.

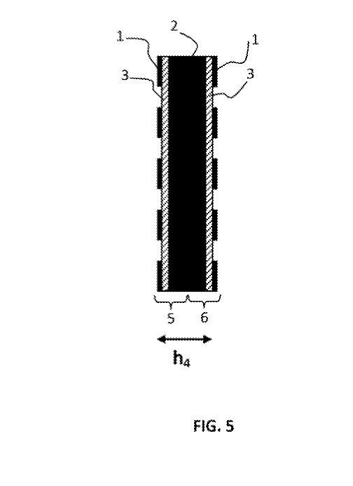

FIG. 5 illustrates an example of an ultrathin spectral converter design, where a broadband absorber 5 and selective emitter 6 share the same backplane 2. This design performs with high optical efficiency and permits the development of thinner structures by removing the requirement for a substrate. The total thickness of such a design, referred to as h₄, may be as thin as 150 nm.

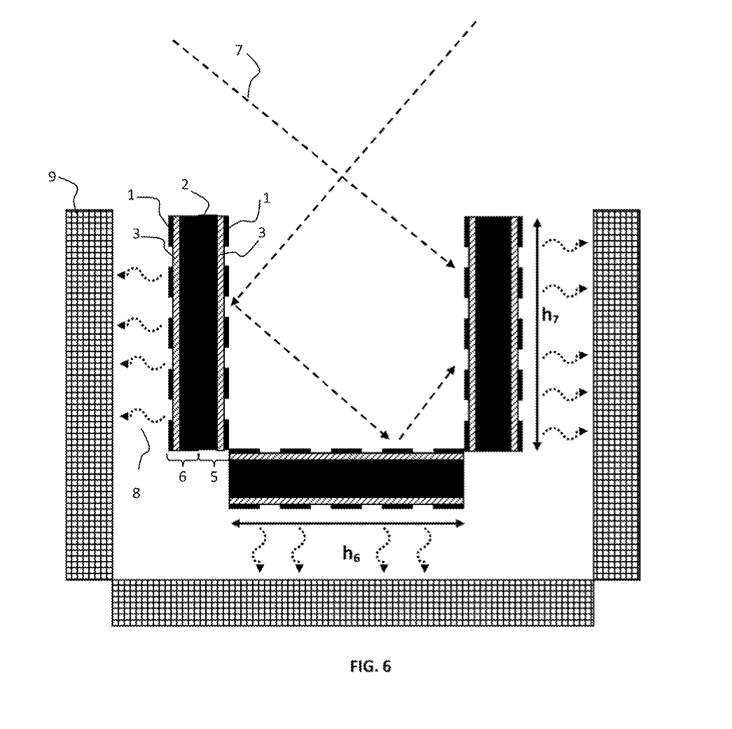

FIG. 6 illustrates an example cuboid design for efficient trapping of solar irradiation by a set of broadband absorbers 5. Sets of selective emitters 6 sharing the same backplane 2 with the broadband absorbers form spectral converters. The spectral converters are combined with photovoltaic cells 9 which are arranged in a similar cuboid arrangement such that emitted radiation is efficiently collected 8 for generation of current. The width of a spectral converter h₆, h₇ may be one millimeter or higher.

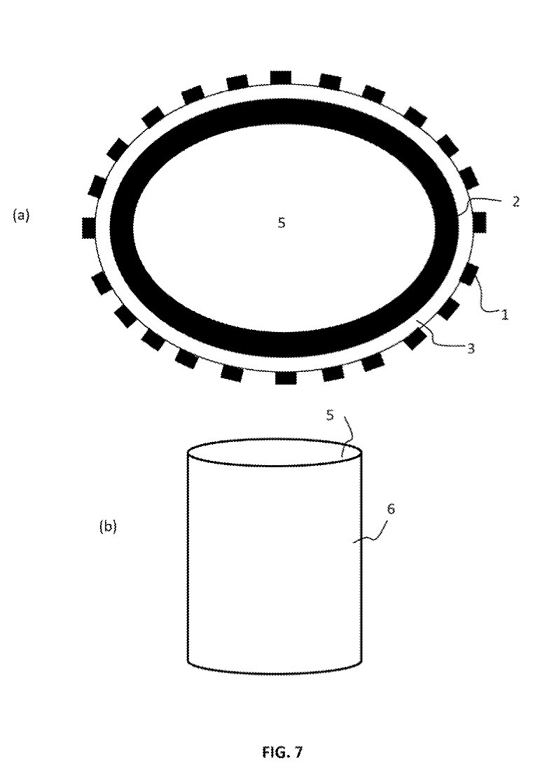

FIG. 7(a) illustrates another example of an ultrathin refractory metamaterial selective emitter, this time applied to a curved surface. This arrangement may be used, e.g., with solar thermophotovoltaic devices and thermophotovoltaic devices. FIG. 7(b) shows a perspective image of a cylindrical design, wherein a selective emitter(s) is coupled to the side surface of the cylinder and a broadband absorber(s) is coupled to the top surface of the cylinder.

FIG. 8 shows an example of the schematic of a refractory near perfect broadband absorber metamaterial 5 integrated with a thermoelectric device layer 15 on one surface in order to provide a temperature difference to produce electric current. The thermoelectric device 15 is further coupled to a cooling layer 12 in order to maintain a desired temperature gradient between the face of the absorber and the face of the cooling layer (i.e. the system). The cooling layer may comprise a passive heat sink, a flowing liquid (like a river), wind, etc. This arrangement is referred to as a solar thermoelectric device. The application of refractory broadband metamaterial absorbers, as disclosed herein, enables higher operation temperatures and thus greater current generation.

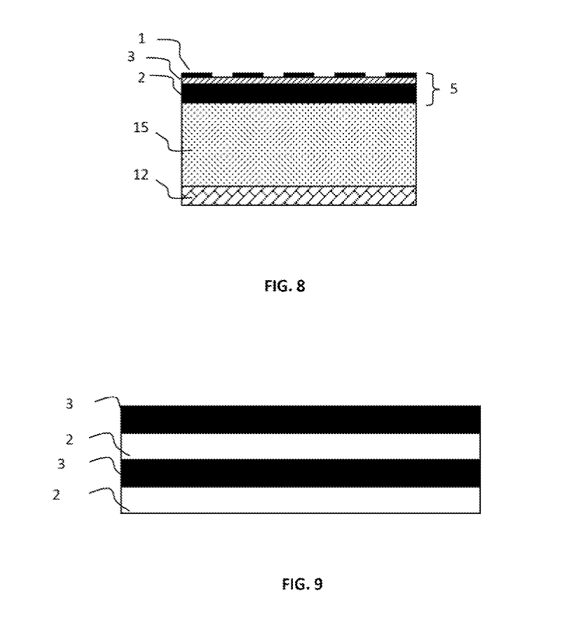

FIG. 9 shows another example arrangement of refractory plasmonic and dielectric materials for broadband absorption and selective emission. The number of layers and thicknesses of each layer may be varied in order to achieve optimal performance at specific wavelength ranges and depending on the operation mode (i.e., as absorber or as emitter). Similar efficiencies may be achieved by changing one or more other parameters of this design, such as types of layers, nanostructure arrangement, and thickness, etc.

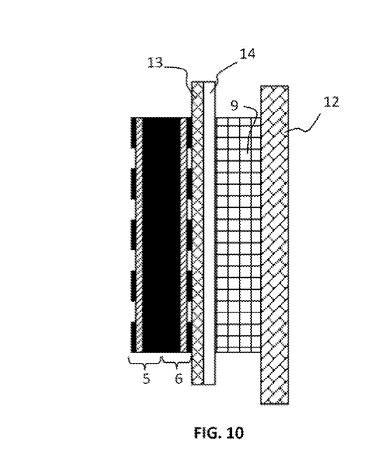

FIG. 10 depicts a near field arrangement example for high efficiency energy transfer between a selective emitter metamaterial and a photovoltaic cell. A thin layer of thermal insulator and liquid/gas flow for semiconductor cooling is applied where both elements have to be transparent in the spectral region of radiation from the emitter.

FIG. 11 shows scanning electron microscope images of plasmonic nanostructures comprising gold (11.a) and titanium nitride (11.b). The samples were fabricated with electron beam lithography and used for optical testing and performance comparison. After illumination of each sample with a laser at a wavelength of 550 nm, the gold structures show significant damage (11.c), while the titanium nitride sample remains substantially undamaged.

A body integrated with a near perfect absorber disclosed herein may be heated to elevated temperatures by converting sunlight into energy. The heated body, in turn, may radiate infrared light corresponding to its temperature. Provided that the body is heated sufficiently, the body obtains radiation peaks in the near infrared to mid-infrared windows.

Near perfect absorbers, as disclosed herein, integrated with surfaces that provide engineered emission may also be used for efficient light harvesting with thermophotovoltaic devices. Energy absorbed in the visible spectrum may be converted to energy emitted (through selective emission) at longer wavelengths, which may be further efficiently absorbed by, for example, a low band-gap semiconductor.

Plasmonic refractory nanostructures may also be used as selective narrowband emitters in the infrared region for applications including, but not limited to, thermophotovoltaics. Selective emission is obtained with particular arrangements of plasmonic nanostructures, which are grown at a short distance (gap) from the plasmonic backplane. Various shapes of nanostructures including, but not limited to, nanospheres, nanodisks, nanorods, nanocubes, and nanotriangles, and various arrangements of one or more of such shaped nanostructures provide selective narrowband emission in the near infrared region. Such arrangements may be periodic (comprising repeating nanostructure cells) or they may be random/non-periodic (comprising one or more types of repeating nanostructure cells).

Due to the non-stoichiometric nature of most ceramics, their optical properties may be adjusted by changing their growth parameters. For example, changing the substrate temperature is an effective way of getting titanium nitride films of varying optical responses. A broadband absorber metamaterial, as disclosed herein, requires a material with plasmonic properties. At the same time, however, strongly metallic materials must be avoided in order to increase impedance matching at the metamaterial-air interface. For example, titanium nitride may be grown at 400° C. under high vacuum with argon and nitrogen flow. It is noted that titanium nitride films grown at higher temperatures tend to have a larger magnitude of real part of permittivity and may thus not be desirable. The adjustability of the optical behavior of titanium nitride is one of its advantages over noble metals (and other plasmonic materials).

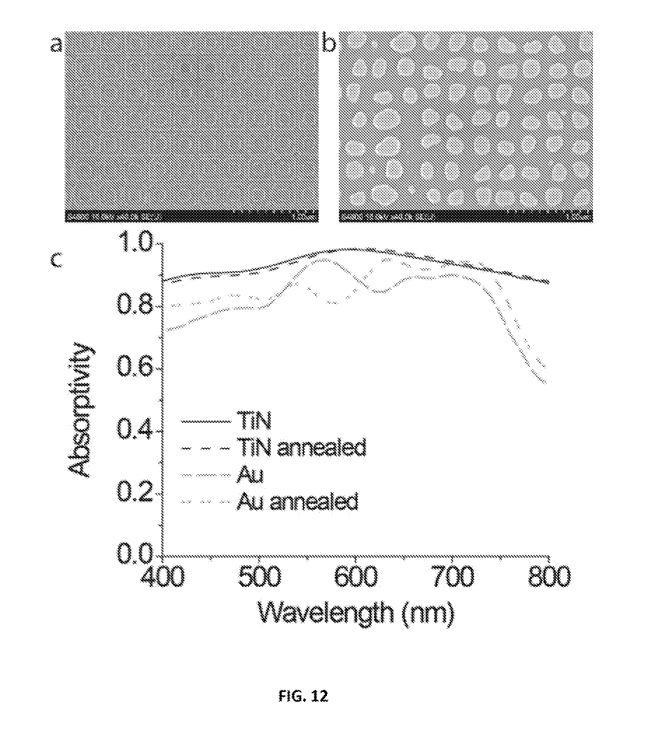

Thermal tests, performed on a heating stage and furnace, confirm that TiN nanostructures retain their shapes and optical properties after 1 hour of annealing at 800° C. under vacuum conditions. FIG. 12.a shows an SEM image of a TiN absorber sample after such an annealing process. FIG. 12.b shows a similar sample made of a conventional plasmonic material (in this case, Au). FIG. 12.c shows a graph of the absorption of the samples before and after the thermal test. The performance of the TiN sample remains the same after the thermal test, while the conventional sample exhibits a large change after the thermal test, in the form of shape deformations. Moreover, a TiN sample absorber provides a broader and larger absorbance in comparison with Au, both before and after the heat test.

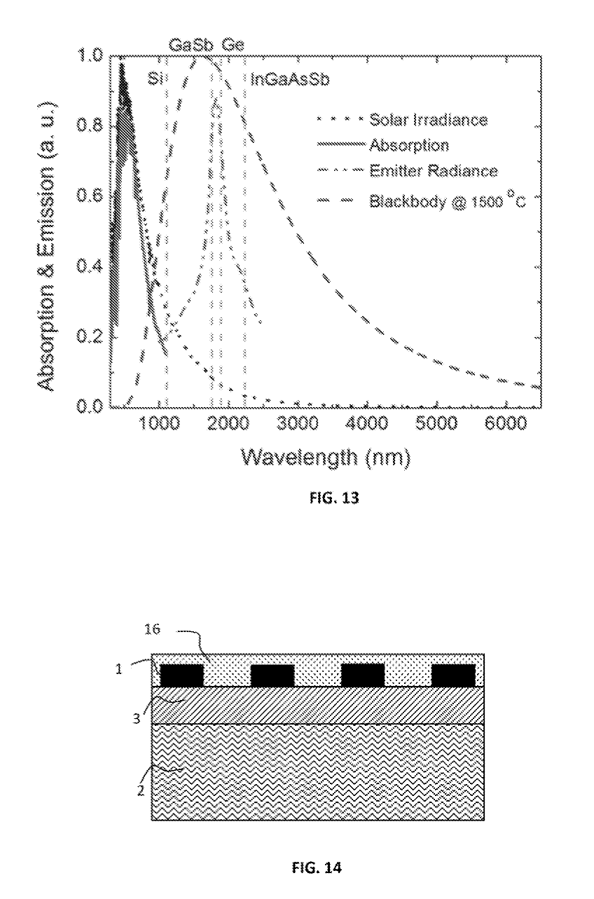

FIG. 13 shows a graph of the narrowband emission obtained from a TiN selective emitter metamaterial (Emitter Radiance), as well as solar irradiance, broadband absorption of the TiN metamaterial (Absorption), a blackbody emission spectrum at 1500° C. (Blackbody @1500° C.), and the wavelengths corresponding to the bandgap energies of semiconductors used for thermophotovoltaic devices (vertical dashed lines).

Refractory materials with poor plasmonic properties may be doped with inclusions of up to 10% in order to obtain a plasmonic response required for enhanced performance, as described herein, of metamaterial absorbers or emitters.

Plasmonic materials with low melting points may be doped with inclusions up to 10% in order to achieve high temperature durability within the metamaterial absorbers and emitters described herein.

In either of the above situations, the dopant may be any metal (preferably those with a strong plasmonic response, such as silver, gold, aluminum, etc.). The dopant may also be nitrogen, oxygen, carbon, etc. (and created in a manner similar to the conversion of Ti to TiN, as discussed herein).

A common problem for many refractory materials is oxidation at high temperatures. Although refractory plasmonic materials have a very high melting point, they tend to oxidize at temperatures above 100 degrees Celsius. In the event of oxidation due to a failure of sealing, transition metal nitrides may be nitridized via annealing processes at temperatures above 700° C., under nitrogen rich gas flow such as ammonia. The nitridization process may be used as a recovery step in order to reduce fabrication and maintenance costs of the metamaterial structures described herein.

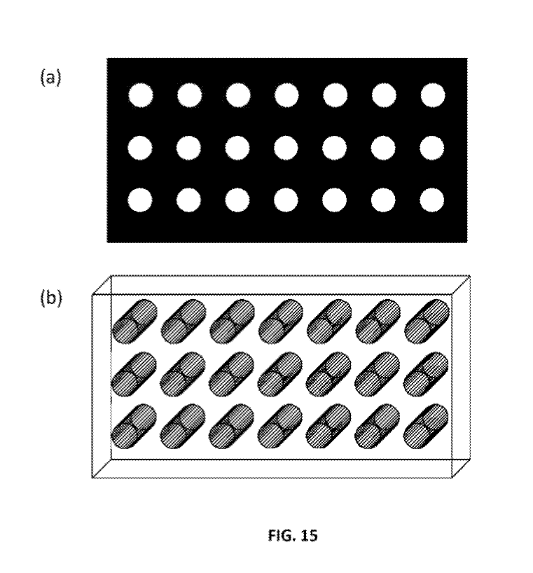

The metamaterial absorbers and emitters of the present invention may further be coated with an optically transparent thin film of refractory dielectric material (i.e. coating) in order to increase the oxidation resistance (the coating having a thickness between 5 nm and 3,000 nm, and comprising either non-metal ceramics, oxides, carbides, other refractory materials, etc.). FIG. 14 shows an example illustration of such modification by depositing a protective layer 16. This protective layer helps avoid element failure in the event of exposure to an environment containing oxygen. Such a device may be operated without vacuum sealing, especially in cases where pumping and maintenance are not feasible. When vacuum sealing or an inert gas filling is employed, the protective layer reduces restrictions on the quality of the vacuum sealing or gas filling. For example, it provides longer durability in situations where the sealing fails.

In another aspect of the present invention, the absorber is further coupled to a thermoelectric device, the absorber absorbing sunlight of a particular wavelength (based on the geometric design of the nanostructures and other thin films) and increasing the temperature of the system to a gradient sufficient for electric power generation by the thermoelectric device which is attached to the absorber (and any other thin films comprising the system).

In yet another aspect, a thermophotovoltaic system simply comprises a selective refractory metamaterial emitter receiving heat from a burning fuel or the residual heat from an already “working process” (e.g., engines performing other work, metal casting processes, fossil fuel burning for other power generation, propane and other material processing furnaces, etc.). The heat may be received, virtually, from any artificial or natural resource producing heat. Applicable “working processes” also include fuel fired systems designed for TPV technology (e.g., high energy density, portable electric power generators for, e.g., military applications, etc.). The emitter receives heat from (i.e. is heated by) the process/fuel (rather than, e.g., an absorber), and the emitter exhibits selective emission (based on its geometry and structure) in order to illuminate a photovoltaic cell (to which it is coupled) for electric power generation.

The present invention may further include for example, a solar vaporization system, comprising a nanosnuctured refractory plasmonic material (as disclosed above) for dispersion into a liquid. This plasmonic material is then heated under sunlight and thus increases the temperature of the liquid in which it exists. As the liquid heats up, a vapor is produced from the liquid electric power is generated from the vapor. In one particular embodiment, the liquid of this system is seawater (i.e. saltwater), and the vapor produced may be used for a desalination process when it is converted back into a liquid phase.

The description of a preferred embodiment of the invention has been presented for purposes of illustration and description. It is not intended to be exhaustive or to limit the invention to the precise forms disclosed. Obviously, many modifications and variations will be apparent to practitioners skilled in this art. It is intended that the scope of the invention be defined by the following claims and their equivalents.

Moreover, the words “example” or “exemplary” are used herein to mean serving as an example, instance, or illustration. Any aspect or design described herein as “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

What is claimed is:

1. A solar thermophotovoltaic system, comprising:
a selective refractory ceramic metamaterial ultimate absorber configured to absorb electromagnetic energy in the visible and near infrared spectral region, and heating to temperatures above 100 degrees Celsius where a blackbody emission in the near infrared spectral region is enabled; and
a selective refractory ceramic metamaterial emitter configured to radiate electromagnetic energy matching with a bandgap of a photovoltaic semiconductor in the near infrared spectral region.

2. The system of claim 1, wherein the absorber and emitter comprise a backplane thin film of a refractory plasmonic ceramic, a spacer comprising a thin film of a refractory dielectric material, and a first arrangement of nanostructures of a refractory plasmonic ceramic.

3. The system of claim 1, wherein the absorber and the emitter are fabricated using a lithographic method.

4. The system of claim 1, wherein the absorber and the emitter are fabricated using a powder dispersion or a powder metallurgy method.

5. The system of claim 2, wherein the emitter comprises a backplane thin film of a refractory plasmonic material, a spacer comprising a thin film of a refractory dielectric material, and a second arrangement of nanostructures of a refractory plasmonic material.

6. The system of claim 5, wherein the arrangements of nanostructures comprise a non-periodic arrangement of repeating individual nanostructure cells, wherein an individual nanostructure cell comprises a shape of sub-wavelength width, d, and a height between 5 nm and 500 nm, each cell being separated by a pitch distance, p, between 20 nm and 1,000 nm, defined by a relationship of 1 p/6<d<5 p/6.

7. The system of claim 1, wherein the emitter comprises a perforated metallic film with a thickness greater than 50 nm and with perforations smaller than 3,000 nm in a periodic arrangement or a random arrangement.

8. The system of claim 1, wherein the absorber and the emitter each further comprise a refractory dielectric coating for oxidation resistance, the coating having a thickness between 5 nm and 3,000 nm.

9. The system of claim 2, wherein the backplane thin film forms a bottom layer of the absorber, the first arrangement of nanostructures forms a top layer of the absorber, and the spacer is located between the bottom and top layers, together forming an arrangement to convert electromagnetic energy into heat energy.

10. The system of claim 2, wherein the emitter releases spectrally selective radiation in a near infrared spectral region.

11. The system of claim 2, wherein the first arrangement of nanostructures comprises a periodic arrangement of repeating individual nanostructure cells.

12. The system of claim 2, wherein the backplane thin film has a thickness of at least 50 nm.

13. The system of claim 2, wherein the spacer has a thickness between 1 nm and 1,000 nm.

14. The system of claim 2, wherein the backplane thin film, spacer, and nanostructures comprise metal-nitrides, -borides, -oxides, -carbides, -sulfides, or a combination thereof.

15. The system of claim 1, wherein the backplane thin film and nanostructures comprise refractory metals with a dielectric permittivity exhibiting zero cross-over at wavelengths below 1,000 nm.

16. The system of claim 15, wherein the backplane thin film and nanostructures are made of tantalum.

17. The system of claim 2, wherein the arrangements of nanostructures comprise nanospheres, nanodisks, nanorods, nanocubes, nanotriangles, nanostars, or a combination thereof.

18. The system of claim 2, wherein the emitter exhibits selective emission at a wavelength between 500 nm and 4,000 nm.

19. The system of claim 2, wherein the absorber is further coupled to a thermoelectric device, the absorber absorbing sunlight and increasing the temperature to a gradient sufficient for electric power generation by the thermoelectric device.

20. A thermophotovoltaic system, comprising: a selective refractory ceramic plasmonic metamaterial emitter coupled to a photovoltaic cell, said emitter receiving heat from a working process, said working process heating the system, and the emitter exhibiting a selective emission of a radiation for illuminating the photovoltaic cell and thus generating electric power.

21. The system of claim 1, wherein the absorber and emitter are TiN or ZrN metamaterials.
